(19) United States
(12) Patent Application Publication
(10) Pub. No.: US 2010/0243047 A1
(43) Pub. Date: Sep. 30, 2010

(54) MADE TO A JUNCTION BOX FOR ELEMENTS CAPABLE OF COLLECTING LIGHT

(76) Inventors: Hans-Werner Kuster, Aachen (DE); Bernhard Reul, Herzogenrath (DE); Walter Stetter, Illertissen (DE)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/738,490

(22) PCT Filed: Oct. 13, 2008
(86) PCT No.: PCT/EP08/63745

§ 371 Date: Jun. 14, 2010

(30) Foreign Application Priority Data
Oct. 9, 2007 (US) 60978507
Oct. 16, 2007 (FR) 0758351

(51) Int. Cl. H01L 31/00

(52) U.S. Cl. 136/256

(57) ABSTRACT

The invention related to an element capable of collecting light, comprising a first substrate (1) having a glass function and forming a protective cover and a second substrate (1′) forming a support plate, said substrates sandwiching between two electrode-forming conductive layers at least one functional layer (7) based on an absorber material for converting light energy into electrical energy. The second substrate (1′) is provided with at least one orifice which opens at the level of the conductive layers and within which a pressing member (19) passes, said pressing member being held within a cavity made in an electrical connection device (9) fastened to said substrate (1′).

The present invention relates to improvements made to a junction box for elements capable of collecting light.

It is known that elements capable of collecting light of the photovoltaic solar cell type comprise an absorber agent and two electrodes electrically insulated from each other. The whole assembly is encapsulated between two substrates, one of which constitutes a protective substrate having a glass function, so as to allow light to pass through it, and the other substrate forms a support and is therefore not necessarily transparent. The electrodes are essentially characterized by an electrical resistance as low as possible and good adhesion to the absorber layer and, where appropriate, to the substrate. The electrodes are most often made of metal or from a metal oxide, for example based on molybdenum, silver, aluminum, copper, doped zinc oxide, or tin oxide.

Ternary chalcopyrite compounds, which may act as absorber, generally contain copper, indium and selenium. Layers of such absorber agent are referred to as CISe₂ layers. The layer of absorber agent may also contain gallium (e.g. Cu(In,Ga)Se₂ or CuGaSe₂), aluminum (e.g. Cu(In,Al)Se₂) or sulfur (e.g. CuIn(Se,S)). They are denoted in general, and hereafter, by the term chalcopyrite absorber agent layers.

Another family of absorber agent, in the form of a thin film, is either based on silicon, which may be amorphous or microcrystalline, or based on cadmium telluride (CdTe). There also exists another family of absorber agent based on crystalline silicon or silicon wafer, deposited as a thick film, with a thickness between 50 μm and 250 μm, unlike the amorphous or microcrystalline silicon system, which is deposited as a thin film.

For these absorber agents of various technologies, it is known that their photovoltaic (energy conversion) efficiency is appreciably reduced upon moisture penetration, by water molecules in liquid or vapor form diffusing thereinto, even without any visible deterioration in the optical appearance.

This is why the operation of assembling a solar cell, which consists in joining together, between two substrates, one that forms a cover and one that forms a support, all the layers and the electrical connections for connecting said cell to the outside in order to utilize the energy produced, must be carried out with very great care, particularly ensuring that the solar module is sealed. In particular, this sealing of the module is carried out, on the one hand, along the edge of the cell, for example by depositing a bead of sealant using an extrusion technique, and, on the other hand, at the orifices for passage of the electrical connections.

As mentioned above, the layer of chalcopyrite absorber agent is sensitive to moisture and when assembling the solar cell it is necessary to ensure that any moisture penetration is prevented. The sensitive points of the cell, which may constitute points of moisture ingress, are, on the one hand, the peripheral bead of sealant and, on the other hand, the orifices needed for passage of the electrical connections. Solar cell manufacturers have developed, in collaboration with chemists, compositions for sealants (or for a combination of sealants, one sealant being intended for example to act as a barrier to liquid water and the other acting as a barrier to water vapor) that fulfill their function on the periphery of the cell, but to a lesser extent at the orifices needed for the electrical connection.

At these orifices, moisture can wick up along the wires toward the multilayer stack, this phenomenon possibly being exacerbated by the slackening that results owing to the fact that the electrical connections generally consist of flexible connectors.

The object of the present invention is therefore to alleviate the drawbacks of the prior solutions by providing a connection device that is sealed at the input and output orifices for the passage of the electrical connections of the solar cell.

For this purpose, the element capable of collecting light, comprising a first substrate forming a protective cover and a second substrate forming a support plate, said substrates sandwiching between two electrode-forming conductive layers at least one functional layer based on an absorber material for converting light energy into electrical energy, is characterized in that the second substrate is provided with at least one orifice which opens into the conductive layers and within which a pressing member passes, said pressing member being held within a cavity made in an electrical connection device fastened to said substrate.

In preferred embodiments of the invention, one or more of the following arrangements may optionally be employed:
the pressing member is in contact with a strip of conductive material attached to a surface portion of the conductive layer;
the cavity surrounding the pressing member is filled with a fluid protecting the pressing member from oxidation;
the electrical connection device is provided with a plurality of concentric recessed or raised regions around the pressing member that form sealing barriers;
the electrical connection device comprises a plurality of electrical connection means in electrical relationship, on the one hand, with the pressing member and, on the other hand, with a use network and/or with a bypass diode.

According to another aspect, the subject of the invention is also the connection device suitable for being used with the element capable of collecting light described above, which comprises a substantially parallelepipedal box, the face of the device that is intended to be in contact with the lower face of the substrate having an orifice receiving a pressing member intended to come into electrical contact with at least one electrode deposited on a surface portion of a substrate.

Other features, details and advantages of the present invention will become more clearly apparent on reading the following description given by way of illustration but implying no limitation, with reference to the appended figures in which:

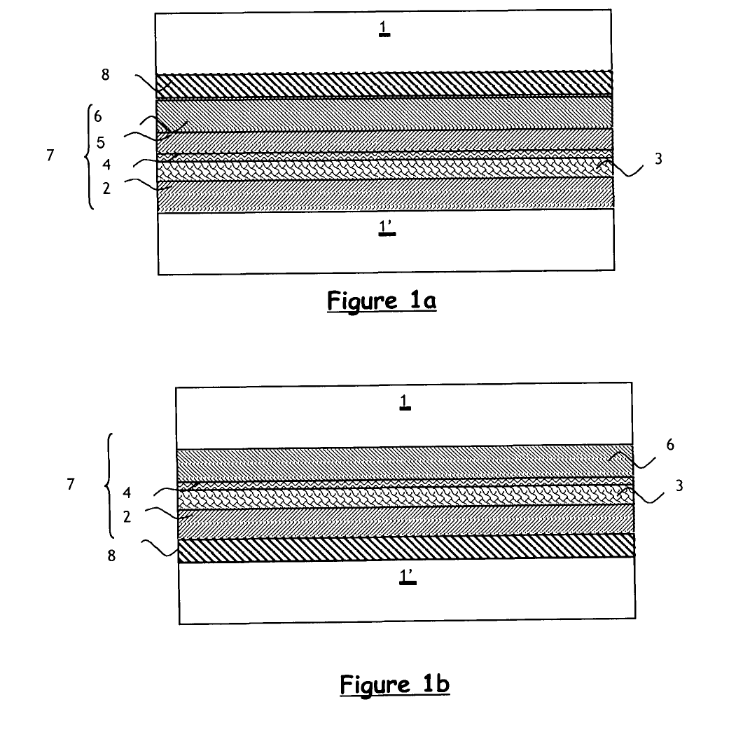

FIGS. 1a and 1b are schematic views of an element capable of collecting light according to the invention;

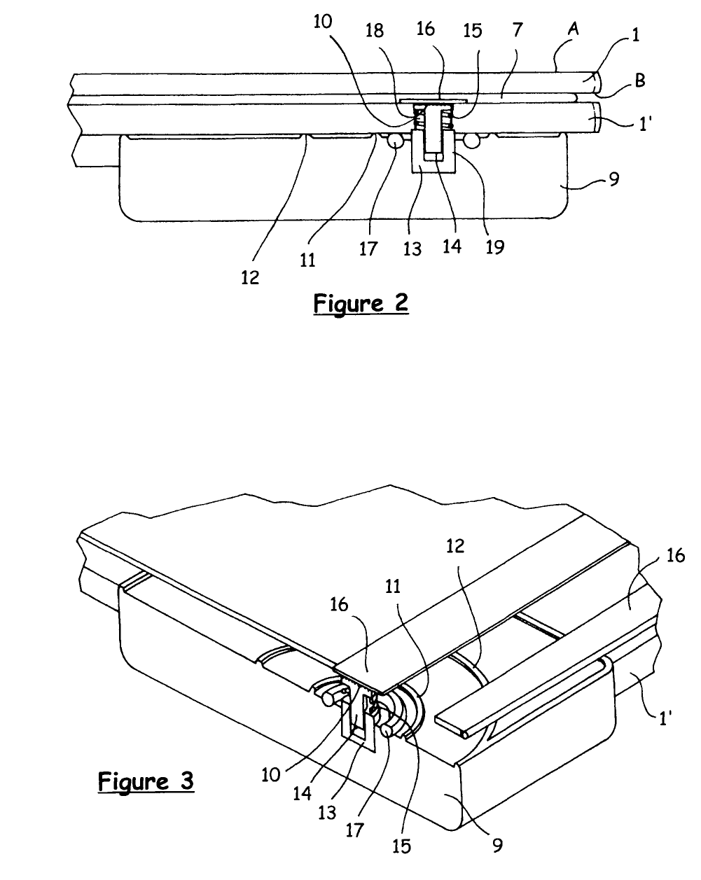

FIG. 2 is a sectional view of an element according to the invention, this section being made through an electrical connection device;

FIG. 3 is a perspective view of the connection device shown in FIG. 2;

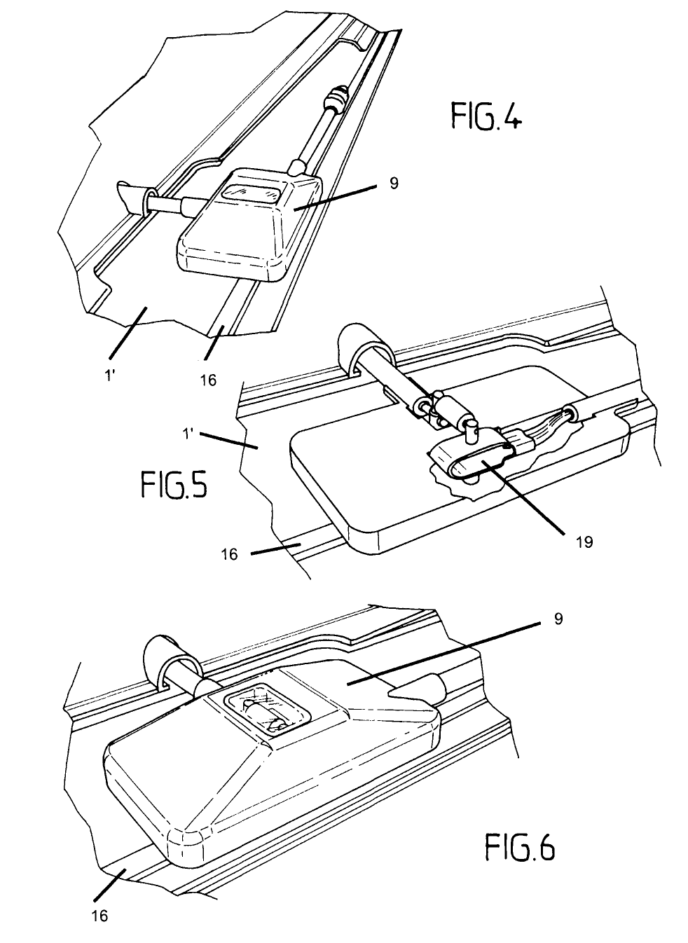

FIG. 4 is a perspective view of a connection device according to another embodiment of the invention;

FIG. 5 is a perspective view of the device shown in FIG. 4, the diode and the pressing member being visible; and

FIG. 6 is a perspective view of the device shown in FIG. 4, only the diode being visible.

FIG. 1a shows an element capable of collecting light (a solar or photovoltaic cell). Schematically, two substrates 1 and 1′, the substrate 1 forming the cover and the substrate 1′ forming the support, at least one of which (the substrate 1 in this case) is necessarily transparent in order to let light pass through it, sandwich a multilayer stack 7 comprising, between electrode-forming electrically conductive layers 2, 6, a functional layer 3 based on an absorber agent for converting light energy into electrical energy.

The substrate 1 forming the cover is transparent and may for example be made entirely of glass. It may also be made of a thermoplastic polymer, such as a polyurethane, a polycarbonate or a polymethyl methacrylate.

Most of the mass (i.e. for at least 98% by weight) or even all of the substrate having a glass function consists of material(s) exhibiting the best possible transparency and preferably having a linear absorption of less than 0.01 mm⁻¹ in that part of the spectrum useful for the application (solar module), generally the spectrum ranging from 380 to 1200 nm.

The substrate 1 forming the cover according to the invention may have a total thickness ranging from 0.5 to 10 mm when it is used as protective plate for a photovoltaic cell produced from various technologies, e.g. CIGS, amorphous silicon, microcrystalline silicon. In this case, it may be advantageous to subject this plate to a heat treatment (for example of the toughening type) when it is made of glass.

The substrate 1′ forming the support plate differs from the substrate 1 by the fact that it is not necessarily transparent, and therefore does not necessarily have a glass function.

Deposited on one of the main faces of this substrate 1′ is a first conductive layer 2 having to serve as an electrode. The functional layer 3 based on a chalcopyrite absorber agent is deposited on this electrode 2. When this is a functional layer based for example on CIS, CIGS or CIGSe₂, it is preferable for the interface between the functional layer 3 and the electrode 2 to be based on molybdenum. A conductive layer meeting these requirements is described in European Patent Application EP 1 356 528.

The layer 3 of chalcopyrite absorber agent is coated with a thin layer 4, called a buffer layer, of cadmium sulfide (CdS), or of zinc sulfide (ZnS) or of indium sulfide (IS), making it possible to create, with the chalcopyrite layer, a pn junction. This is because the chalcopyrite absorber agent is generally p-doped, the buffer layer being n-doped. This allows the creation of the pn junction needed to establish an electrical current.

This thin buffer layer 4, for example made of CdS, is itself covered with an adhesion layer 5, generally made of undoped zinc oxide (ZnO).

To form the second electrode 6, the ZnO layer 5 is covered with a layer of TCO (Transparent Conductive Oxide). It may be chosen from the following materials: doped tin oxide, especially doped with boron or aluminum. In the case of doped zinc oxide, especially doped with aluminum, the precursors that can be used in the case of CVD deposition may be zinc and aluminum organometallics or halides. The TCO electrode, for example made of ZnO, may also be deposited by sputtering using a metal or ceramic target.

Furthermore, this conductive layer must be as transparent as possible and have a high light transmission over all the wavelengths corresponding to the absorption spectrum of the material constituting the functional layer, so as not to unnecessarily reduce the efficiency of the solar module.

One or the other of the conductive layers 2, 6 has a sheet resistance of at most 30 ohms per square, especially at most 20 ohms per square, preferably at most 10 or 15 ohms per square. It is generally between 5 and 12 ohms per square.

The stack 7 of thin layers is sandwiched between the two substrates 1 (cover) and 1′ (support) via a lamination interlayer or encapsulant 8, for example made of PU, PVB or EVA. The substrate 1 differs from the substrate 1′ by the fact that it has a glass function, such as a soda-lime-silica glass, so as to form the cover of a solar or photovoltaic cell or a module, and then encapsulated peripherally by means of a sealant or sealing resin. An example of the composition of this resin and its methods of use is described in Application EP 739 042.

If an absorber agent of the silicon type, namely amorphous silicon or microcrystalline silicon, or an absorber agent of the type based on cadmium telluride (CdTe) is used in the form of a thin film, the construction of the element capable of collecting light is produced in the opposite way to that used for the chalcopyrite system. The construction is then referred to as a “superstrate” construction as opposed to what is called the “substrate” construction. The reader may refer to FIG. 1b.

The essential difference lies in the fact that the stack of thin layers is constructed starting from the substrate 1 (the cover). The B face (the main internal face) of the substrate 1 is coated with a first conductive layer 6 having to serve as an electrode. The functional layer based on an absorber agent made of amorphous or microcrystalline silicon or of cadmium telluride is deposited on this electrode.

To form the top electrode 6, the layer is based on a layer of TCO (Transparent Conductive Oxide).

It may be chosen from the following materials: doped tin oxide, especially doped with boron or aluminum. In the case of doped zinc oxide, especially doped with aluminum, the precursors that can be used in the case of CVD deposition may be zinc and aluminum organometallics or halides. The TCO electrode, for example made of ZnO, may also be deposited by sputtering using a metal or ceramic target.

Furthermore, this conductive layer must be as transparent as possible and have a high light transmission over all the wavelengths corresponding to the absorption spectrum of the material constituting the functional layer, so as not to unnecessarily reduce the efficiency of the solar module.

This TCO layer 6, for example based on SnO₂:F or ZnO:Al, is optionally covered with an additional relatively thin (for example 100 nm) undoped dielectric ZnO layer 5 (ZnO). This thin ZnO layer is then covered with the functional layer 3 based on silicon or on cadmium telluride in the form of a thin film. The rest of the stack 7 consists of a second conductive layer 2 serving as an electrode, made of a metallic material or metal oxide. Conventionally, this conductive layer is based on ITO (indium tin oxide) or a metal (copper, aluminum).

One or the other of the conductive layers 2, 6 has a sheet resistance of at most 30 ohms per square, especially at most 20 ohms per square, preferably at most 10 or 15 ohms per square. It is generally between 5 and 12 ohms per square.

The stack of thin layers is sandwiched between the substrates 1 (cover) and 1′ (support) via a lamination interlayer or encapsulant 8 for example made of PU, PVB or EVA. The substrate 1′ forming the support differs from the substrate 1 by the fact that it is not necessarily made of glass and is not necessarily transparent. It acts as a support and is encapsulated with the other substrate 1 peripherally by means of a sealant or sealing resin. An example of the composition of this resin and of its methods of use is described in Application EP 739 042.

A solar module as described above must, in order to be able to operate and deliver an electrical voltage to an electrical distribution network, be provided with electrical connection devices.

FIGS. 2 and 3 show in detail an electrical connection device 9. This connection device 9 is positioned on the back of the solar module, fastened by adhesive bonding or by any similar means (welding, adhesive) to the lower face of the module. Preferably there are two connection devices per module (one per electrode), for electrically connecting the module to a user interface (generally consisting of an electronic device for converting a DC voltage into an AC voltage compatible with the distribution network).

This electrical connection device 9 takes the form of a unit or box and is obtained, for example, by a plastic injection molding process. That face of the box intended to be in contact with the lower face of the substrate 1′ has a blind orifice and a plurality of concentric recessed or raised regions 11, 12 around this orifice.

The orifice 9 accommodates a pressing member 19 comprising, on the one hand, a fixed part 13 housed in the orifice 9 and a movable part 14 that can move translationally with respect to the fixed part 13 and forming a piston, the assembly making up a resilient connection thanks to the interposition of a spiral spring 15 or the like. Both the fixed part 13 and the movable part 14 are made of an electrically conductive material, such as for example copper.

The head of the piston is provided with a plurality of raised features or rugosities so as to improve the contact at a region located between this head and the electrode-forming conductive layers (2, 6).

To optimize the electrical contact between the head of the piston 13 and the conductive layer 2 or 6, a strip 16 made of a conductive material (for example aluminum, copper, etc.) is deposited in this contact region, this strip 16 being for example ultrasonically welded to a surface portion of the conductive layer 2 or 6.

One embodiment variant of the pressing member 19 is shown in FIG. 5. As can be seen in this figure, the pressing member is produced in the form of a spiral-wound spring to give elasticity to the assembly.

In this FIG. 5, the box 9 in which this pressing member 19 is inserted, obtained by a plastic molding or injection molding technique, in fact has two levels that each form a compartment, a lower level close to the surface of the photovoltaic module and an upper level located opposite the previous one. These levels are separated by a watertight wall so as to make it possible to interact with the diode, represented in the form of a cylinder that can be seen in FIGS. 5 and 6, without fear of breaking the watertightness with the lower level, that is the region in which the pressing member, in electrical contact with the strip 16, is held.

In FIG. 6 the box is shown without the protective cover that covers the diode, which cover is mounted by “clipping” or fitting to the body of the box and can be easily removed if necessary, using, for example, a screwdriver blade.

In FIG. 4 the box completely covers the assembly of the elements inserted inside the box, thus protecting them both mechanically and from any environmental attack.

In FIG. 5 the electrical connection between the pressing member and the electrical wire that has to be connected to the use network is achieved by crimping, but it would not be outside the scope of the invention to weld this electrical wire directly to the resilient pressing member or indirectly via a conductive part that is itself in electrical contact with the resilient pressing member.

A plurality of sealing barriers are formed around the pressing member 19. In particular, an elastomeric O-ring seal 17 is provided, this being compressed against the back of the module when the connection device is attached. The annular space 18 defined between the periphery 14 of the pressing member and the small circumference of the O-ring seal 17 may advantageously be filled, when the connection device is being assembled on the back of the module, with an inert fluid (for example nitrogen gas) so as to avoid any oxidation that could be deleterious to the quality of the electrical connection. As a variant, provision is made to include in the box a cavity intended to accommodate a desiccating agent, this cavity being connected to the annular space 18.

To further limit, or even eliminate, the problems associated with oxidation as a result of ingress of water, both in liquid and vapor form, several beads of sealant (in fact the regions 11, 12) are interposed between the large diameter of the O-ring seal and the perimeter of the module, these beads of sealant produced during manufacture being part of the connection device and forming a chicane.

The exemplary embodiment of the pressing member comprising generally a piston sliding elastically within a housing may be produced by other embodiments allowing the same functions to be carried out with a view to obtaining an identical result. Thus, for example, an assembly of spring washers in a housing, or a shim provided with lugs for cooperating in bayonets formed laterally in a cylindrical housing may for example constitute alternatives to this pressing member, without departing from the scope of the invention.

Included within the connection device during molding are electrical connection means in the form of a first connector (for example an electrical wire), in electrical relationship with the pressing member.

Also included is a second connector, which is intended to be connected to a bypass diode. This is because the photovoltaic solar modules may be connected in series with other modules so as to form assemblies. If one of the modules is obscured by the passing of a cloud for example, a reduction in the current produced in the assembly and the appearance of a current in the reverse direction in the masked module occur simultaneously. The latter effect leads to the dissipation of an excessively large amount of electrical power, which could result in its destruction. Solar modules are therefore equipped as standard with bypass diodes, the function of which is to protect the masked solar cell and at the same time increase the power produced by the assembly.

1. An element, comprising a first substrate forming a protective cover and a second substrate forming a support plate, said first substrate and said second substrate sandwiching a first electrode-forming conductive layer and a second electrode-forming conductive layer and at least one functional layer based on an absorber material for converting light energy into electrical energy, wherein the second substrate comprises at least one orifice which opens at the level of at least one of the first electrode-forming conductive layer or the second electrode-forming conductive layer and within which a pressing member passes, said pressing member being held within a cavity made in an electrical connection device fastened to said second substrate, said connection device being produced in the form of a box.

2. The element as claimed in claim 1, wherein the pressing member is in contact with a strip of conductive material attached to a surface portion of at least one of the first electrode-forming conductive layer or the second electrode-forming conductive layer.

3. The element as claimed in claim 1, wherein the cavity surrounding the pressing member is filled with a fluid protecting the pressing member from oxidation.

4. The element as claimed in claim 1, wherein the box in which the pressing member is inserted has two levels that each form a compartment, a lower level close to the surface of the second substrate and an upper level located opposite the lower level, the lower level and the upper level being separated by a watertight wall so as to make it possible to interact with a diode without fear of breaking the watertightness with the lower level.

5. The element as claimed in claim 1, wherein the electrical connection device comprises a plurality of concentric recessed or raised regions around the pressing member that form one or more sealing barriers.

6. The element as claimed in claim 1, wherein the electrical connection device comprises a plurality of electrical connections in an electrical relationship, with the pressing member and with a use network and/or with a bypass diode.

7. The element as claimed in claim 1, wherein the electrical connection device comprises a reservoir suitable for accommodating a desiccating agent, this reservoir being connected to the cavity.

8. An electrical connection device for an element as claimed in claim 1, wherein the electrical connection device takes the form of a box, the face of said box being adapted to be in contact with the lower face of the second substrate having an orifice receiving a pressing member intended to come into electrical contact with at least one of the first electrode-forming conductive layer or the second electrode-forming conductive layer deposited on a surface portion of at least one of the first substrate or the second substrate.
